(19) United States
(12) Patent Application Publication
(10) Pub. No.: US 2006/0118831 A1
(43) Pub. Date: Jun. 8, 2006

(54) Semiconductor package and manufacturing method thereof

(76) Inventors: Hyun-Ik Hwang, Asan-si (KR); Gil-Beag Kim, Cheonan-si (KR); Sang-Young Kim, Cheonan-si (KR); Yong-Jin Jung, Cheonan-si (KR); Jun-Soo Han, Cheonan-si (KR)

Correspondence Address: HARNESS, DICKEY & PIERCE, P.L.C., P.O. BOX 8910, RESTON, VA, 20195, US

(21) Appl. No.: 11/268,772

(22) Filed: Nov. 8, 2005

(30) Foreign Application Priority Data
Nov. 8, 2004 (KR) 2004-90355

(51) Int. Cl. H01L 27/148

(52) U.S. Cl. 257/229

(57) ABSTRACT

A semiconductor package may include a substrate having a first major surface supporting a substrate pad and a bump pad electrically connected to the substrate pad. The substrate may have a second major surface with a concave part. A substrate window may extend through the substrate and open at the concave part. A semiconductor chip may be mounted on the substrate. The semiconductor chip may have a chip pad exposed through the substrate windows. Additionally, a method may involve forming a concave part in the substrate.

### PRIORITY STATEMENT

This U.S. non-provisional application claims benefit of priority under 35 U.S.C. § 119 of Korean Patent Application No. 2004-90355, filed on Nov. 8, 2004, the entire contents of which are incorporated herein by reference.

### BACKGROUND OF THE INVENTION

1. Field of the Invention

Example, non-limiting embodiments of the present invention relate generally to a semiconductor package, and more particularly, to a WBGA semiconductor package having a substrate window, through which a chip pad may be exposed, and a manufacturing method thereof.

2. Description of the Prior Art

A trend of the electronic industry may be to manufacture an electronic product that may have characteristics, such as (for example) light weight, miniaturized, high operation speed, multi-function, high performance, high reliability, and low production cost. A technology to enable a design for such a product may be package assembly technology. A ball grid array (BGA) package may be one of the packages developed as a result of the electronic industry trend. The BGA semiconductor package may have a smaller mounting area on a motherboard (for example) and improved electrical characteristic, as compared to a conventional plastic package.

On type of BGA semiconductor packages, is known as a window ball grid array (“WBGA”) semiconductor package. A WBGA package may include a substrate having a window. A chip pad of a semiconductor chip may be exposed through the substrate window.

FIG. 1 is a sectional view of a conventional WBGA semiconductor package. As shown in FIG. 1, the WBGA semiconductor package 100 may include a semiconductor chip 110, a substrate 120, a chip-adhesion layer 130, a wire 140, sealants 160 and 170, and a solder bump 150.

The substrate 120 may include an insulating substrate 121 made of insulating material. The insulating substrate 121 may have opposed major surfaces that support conductive patterns. For example, a first major surface of the insulating substrate 121 (e.g., the surface facing upward in FIG. 1) may support a first conductive pattern 122, and a second major surface (e.g., the surface facing downward in FIG. 1) may support a second conductive pattern 126. A solder-resist layer 125, through which the first conductive pattern 122 may be partially exposed, may be provided on the first major surface of the insulating substrate 121. A substrate-insulating layer 127 may be provided on the second major surface of the insulating substrate 121 to cover the second conductive pattern 126. The first conductive pattern 122 may include a substrate pad 123 for an electrical connection to the semiconductor chip 110, and a bump pad 124 for an electrical connection to an external terminal (such as the solder bump 150, for example). A substrate window W may be provided through the substrate 120. The window W may be formed by a punching process, for example.

FIG. 2 is a detailed drawing of the part “D” in FIG. 1. As shown in FIGS. 1 and 2, the chip-adhesion layer 130 is formed on a lower surface of the substrate 120 and fixes the semiconductor chip 110 onto the substrate 120 securely.

The semiconductor chip 110 may include a chip substrate 111 with a chip pad 112. A passivation layer 113 may be provided on the chip substrate 111. The chip pad 112 may be exposed through the passivation layer 113. The semiconductor chip 110 may be mounted on the substrate 120 so that chip pad 112 may be exposed through the substrate window W.

The wire 140 may electrically connect the substrate pad 123 to the chip pad 112 of the semiconductor chip 110 and the wire 140 may be fabricated from gold (Au), for example.

The sealants 160 and 170 may be fabricated from epoxy resin, for example. The sealants 160 170 may be provided to seal the chip pad 112, the substrate pad 123, the wire 140, and sidewalls of the semiconductor chip 110, as shown in FIG. 1. The sealants 160 and 170 may protect the semiconductor chip 110 and the wire 140 from mechanical and/or electrical shocks, for example.

The solder bump 150 may be provided on the bump pad 124. The solder bump 150 may serve as an external terminal of the semiconductor package 100.

Although a conventional WBGA semiconductor package is generally thought to be acceptable, it is not without shortcomings.

For example, if adhesive is excessively applied onto the substrate 120 when forming the chip-adhesion layer 130, and/or if the chip-adhesion layer 130 is excessively compressed when attaching the semiconductor chip 110 to the substrate 120, the intended electrical connections of the conventional WBGA semiconductor package may be difficult to complete. This is because (for example) the adhesive in the chip-adhesion layer 130 may overflow in the direction of F1 as shown in FIG. 2, and onto unintended areas of the semiconductor chip 110 (e.g., the chip pad 112). In some cases, the adhesive may overflow onto and contaminate the chip pad 112, which may inhibit a secure fixing between the wire 140 and the chip pad 112 in a wire bonding process.

The quantity of the adhesive applied onto the substrate 120 and/or the pressure of attaching the semiconductor chip 110 to the substrate 120 may be reduced in an attempt to avoid the “adhesive overflow” phenomenon. But such techniques may be associated with other shortcomings. For example, the application of less adhesive and/or lower pressures may result in empty space (or voids) being formed between the substrate 120 and the semiconductor chip 110. Such voids may occur (for example) when the edge part 130e of the chip-adhesion layer 130 moves in the direction of F2. The voids may increase the likelihood of an unintended separation of the semiconductor chip 110 from the substrate 120. Further, aqueous sealant may flow into the empty space and penetrate through the boundaries between the substrate 120, the chip-adhesion layer 130, and the semiconductor chip 110, which may also weaken the adhesive strength between the semiconductor chip 110 and the substrate 120.

A conventional WBGA package may also have shortcomings associated with a jig, which may be used in a semiconductor package manufacturing process.

FIGS. 3a to 3c are sectional views illustrating a process of attaching a semiconductor chip to a substrate in a conventional manufacturing method for a WBGA semiconductor package. As shown in FIG. 3A, a chip-adhesion layer 130a may be provided between a substrate 120a and a semiconductor chip 110a. The assembly may be compressed between a first jig J1 (which may support the semiconductor chip 110a) and a second jig J2 (which may support the substrate 120a) to attach the semiconductor chip 110a to the substrate 120a. During compression, adhesive in the chip-adhesion layer 130a may flow, and an adhesive overflow Q1, may contact and become attached to the second jig J2. As shown in FIG. 3B, the second jig J2 may be released from the substrate 120a. At this time, the adhesive overflow Q2 may separate from the chip-adhesion layer 130 and remain fixed to (and contaminate) the second jig J2.

As shown in FIG. 3C, another semiconductor chip 110b, substrate 120b, and chip-adhesion layer 130b (which may be different from those of FIGS. 3a and 3b) may be provided and supported between the first jig J1 and the second jig J2 in a subsequent semiconductor chip attaching process. Here, the adhesive overflow Q2 fixed to the upper jig J2 may cause a region of the substrate 120b to be pressed more than the other regions of the substrate 120b, resulting in an application of uneven pressure to the assembly.

As described above, conventional structures and techniques may result in an adhesive overflow that contaminates a chip pad, the penetration of aqueous sealant into boundaries of the chip-adhesion layer, and the contamination of manufacturing jigs, for example.

### SUMMARY OF THE INVENTION

According to an example, non-limiting embodiment of the present invention, a method may involve providing a substrate having a first conductive pattern. The first conductive pattern may include a substrate pad and a bump pad that are electrically connected together. A concave part may be formed in the substrate. A substrate window may be provided through the concave part. A semiconductor chip having a chip pad may be mounted on the substrate so that the chip pad may be exposed through the substrate window.

According to another example, non-limiting embodiment of the invention, a semiconductor package may include a substrate having a first major surface supporting a substrate pad and a bump pad electrically connected to the substrate pad. The substrate may have a second major surface with a concave part. A substrate window may extend through the substrate and open at the concave part. A semiconductor chip may be mounted on the substrate. The semiconductor chip may have a chip pad exposed through the substrate window.

According to another example, non-limiting embodiment of the present invention, a semiconductor package may include a substrate having a major surface with a concave part. A semiconductor chip may be mounted in the concave part.

### BRIEF DESCRIPTION OF THE DRAWINGS

FIG. 1 is a sectional view of a conventional semiconductor package.

FIG. 2 is an enlarged view of part “D” in FIG. 1.

FIGS. 3A to 3C are sectional views illustrating a process of mounting a semiconductor chip in a conventional manufacturing method.

FIGS. 4A to 4L are sectional views illustrating a manufacturing method for a semiconductor package in accordance with an example, non-limiting embodiment of the present invention.

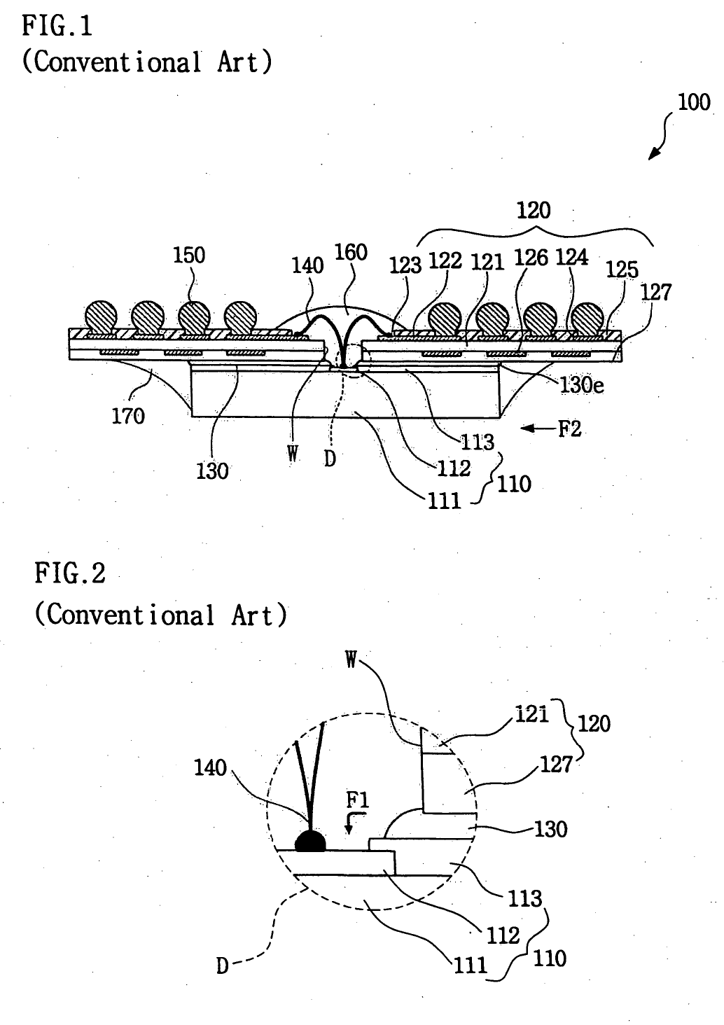

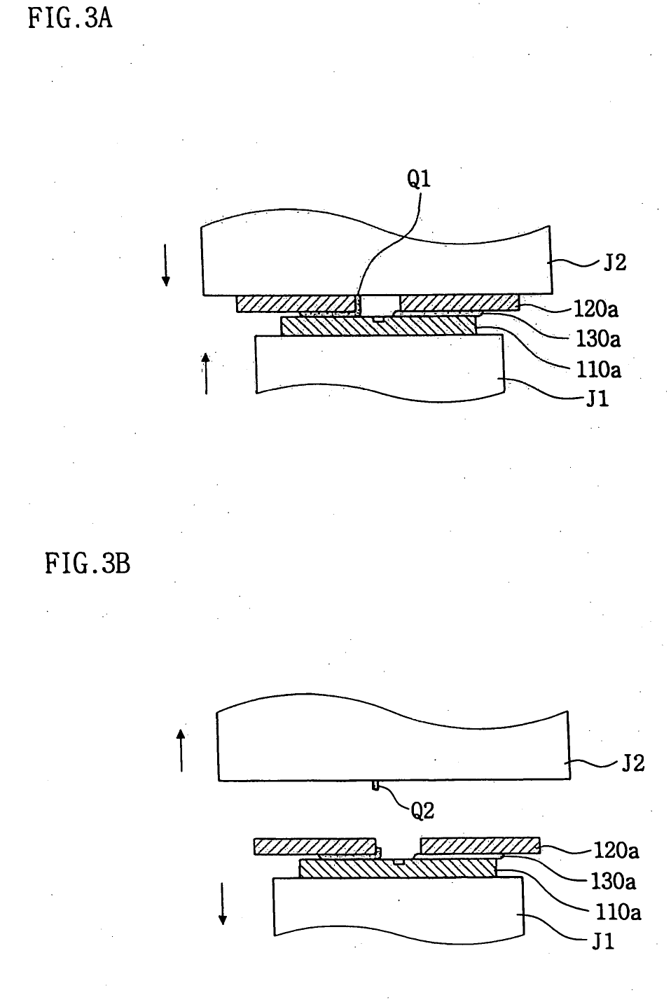

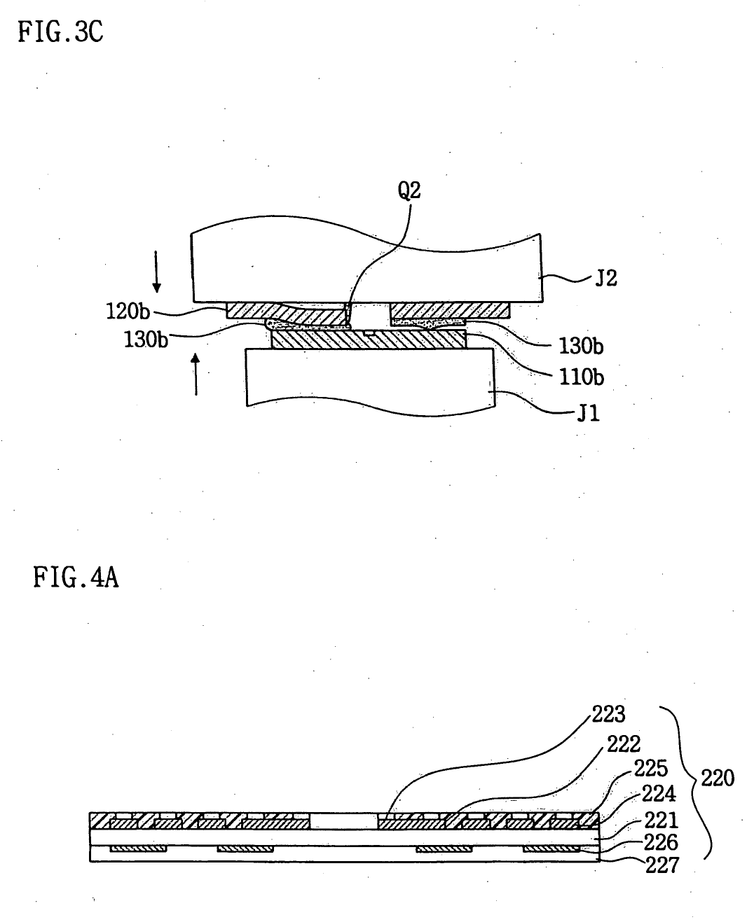

### DETAILED DESCRIPTION OF EXAMPLE, NON-LIMITING EMBODIMENTS

Semiconductor packages and manufacturing methods thereof in accordance with example, non-limiting embodiments of the present invention will be described in more detail with reference to the accompanying drawings. It will be appreciated that the drawings are provided for illustrative purposes only and are not drawn to scale. Rather, to improve clarity, the spatial relationships and relative sizing of the elements illustrated in the various embodiments may have been reduced, expanded or rearranged. The figures are intended to illustrate the general characteristics of methods and devices of example, non-limiting embodiments of the invention. Further, a layer is considered as being formed (or provided) “on” another layer or a substrate when formed (or provided) either directly on the referenced layer or the substrate or formed (or provided) on other layers or patterns overlaying the referenced layer. Well-known structures, materials and processes are not described or illustrated in detail to avoid obscuring example, non-limiting embodiments of the present invention.

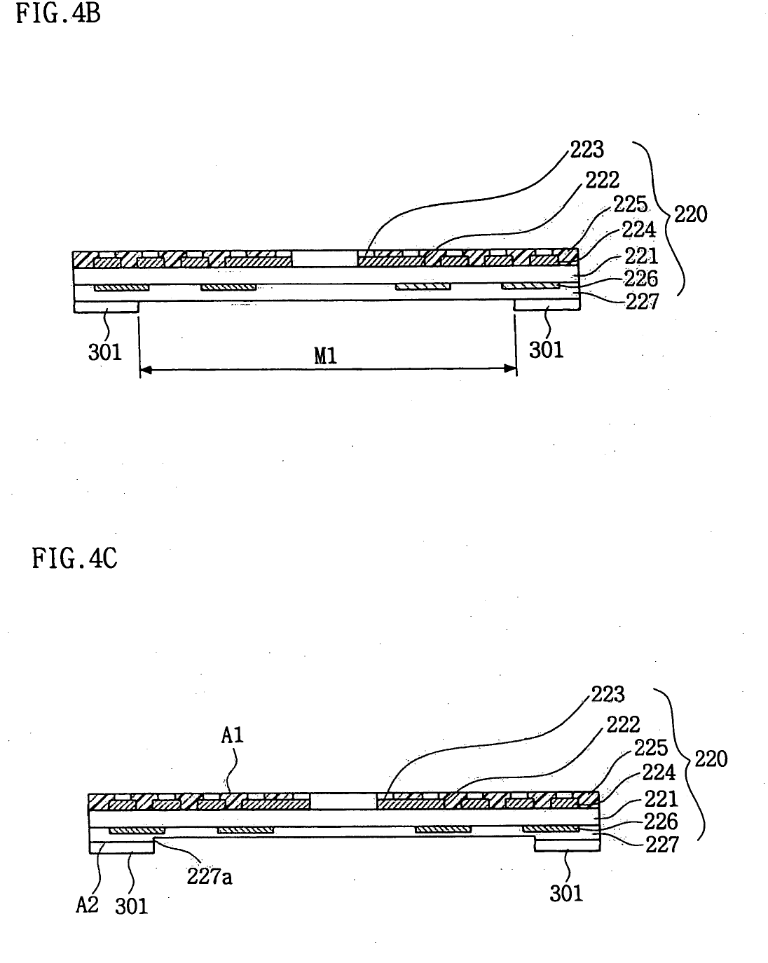

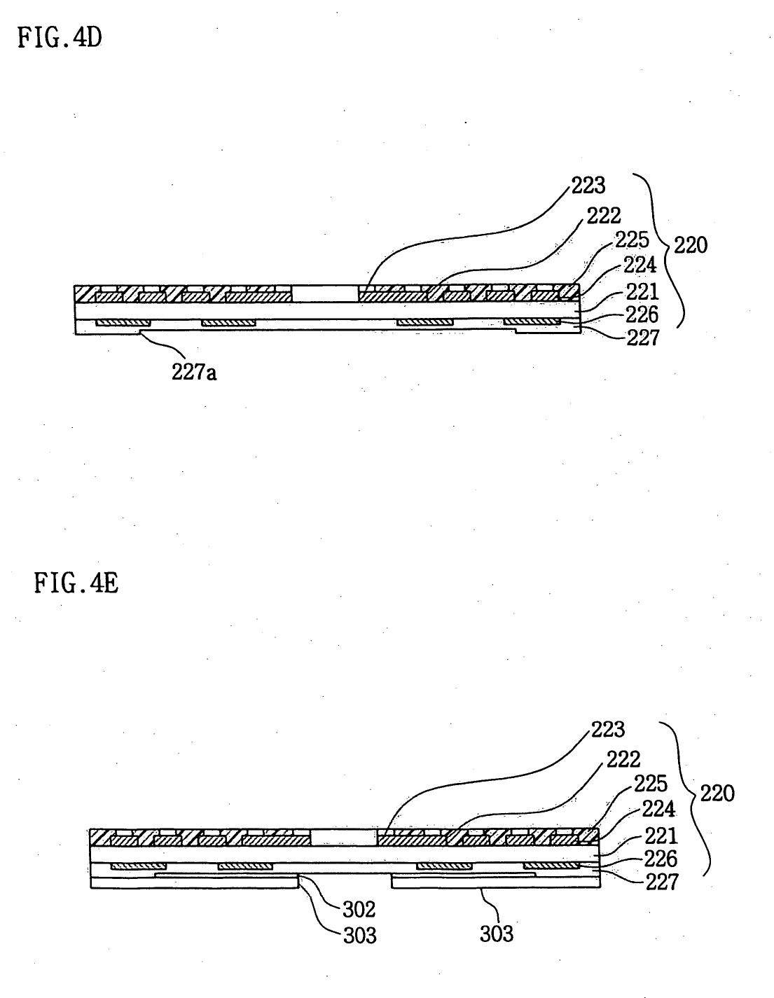

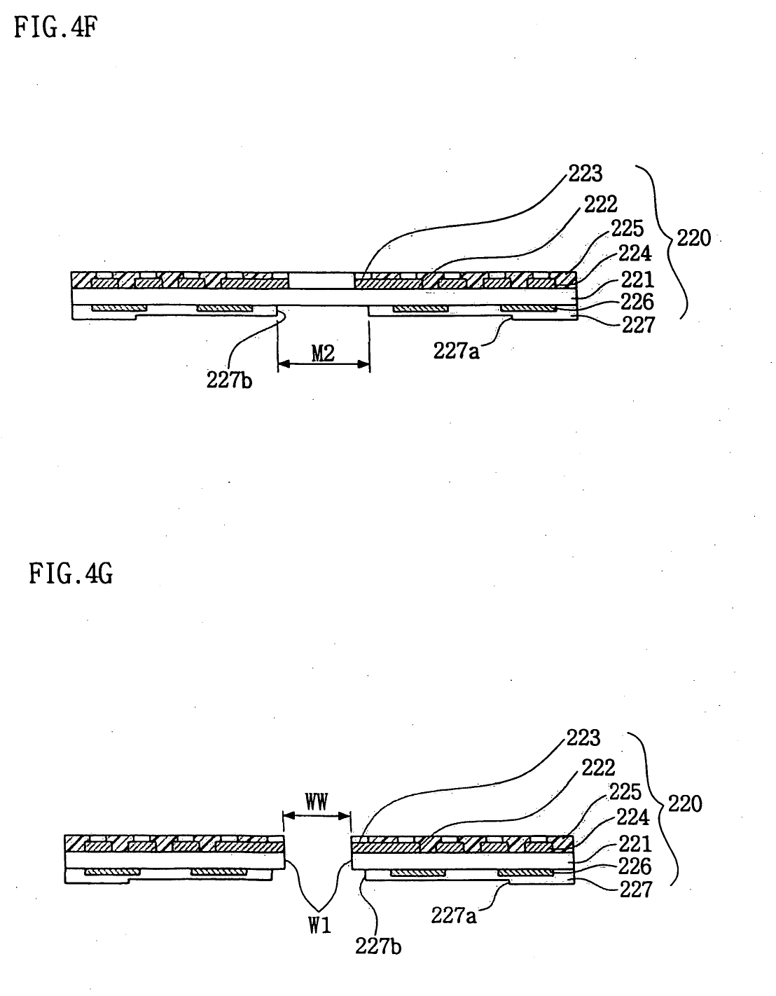

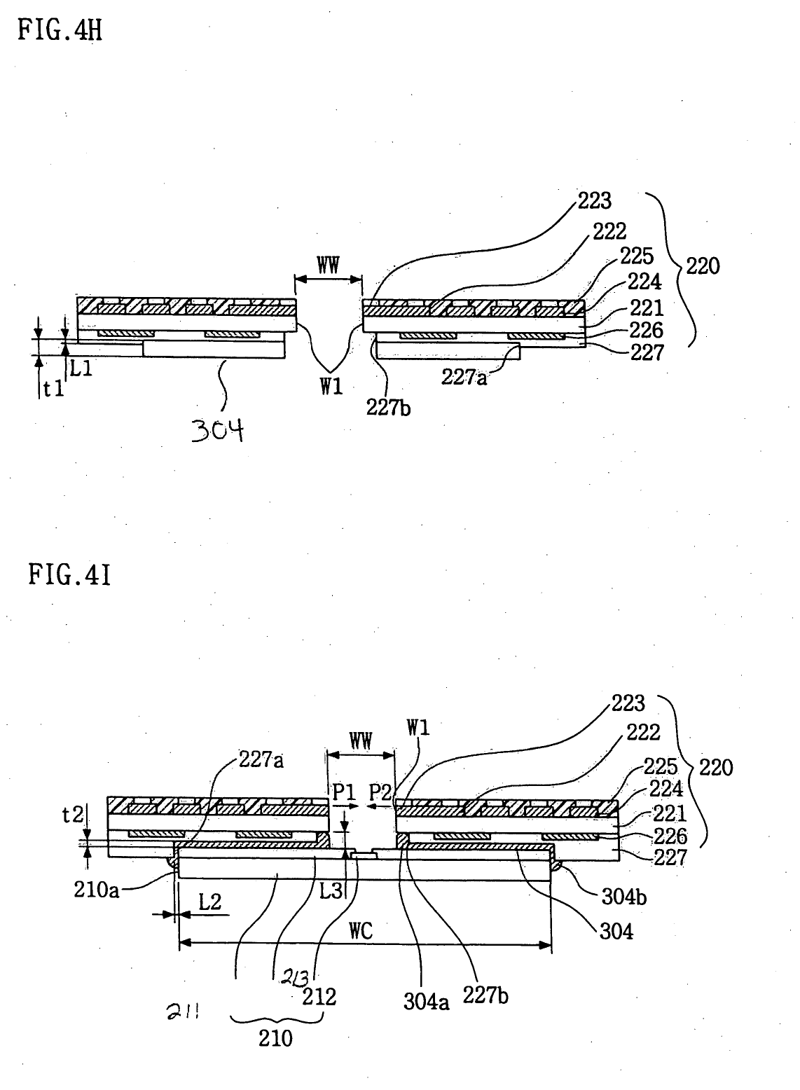

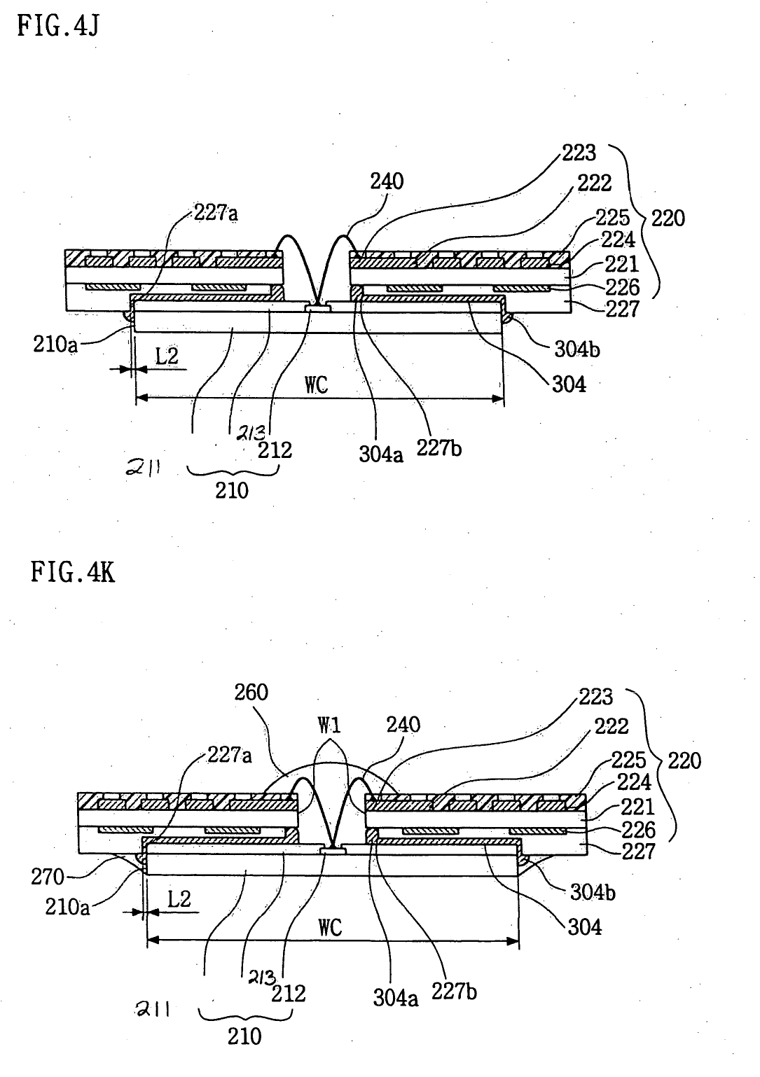

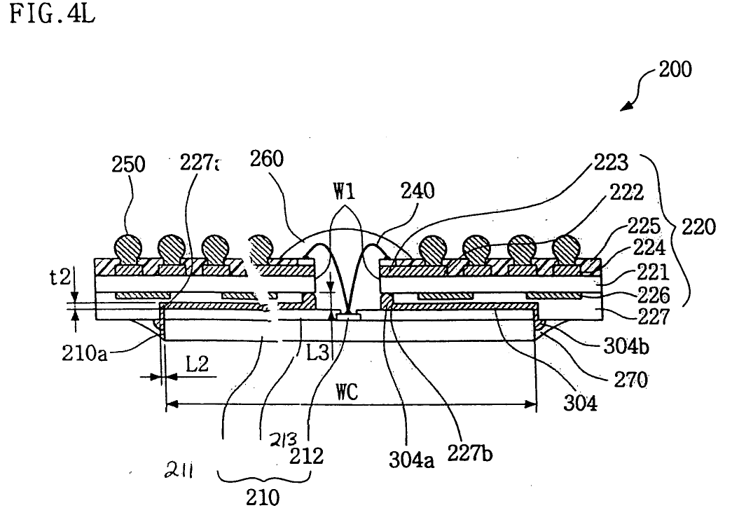

FIGS. 4A to 4L are sectional views illustrating a manufacturing method for a window ball grid array (“WBGA”) semiconductor package in accordance with an example, non- limiting embodiment of the present invention.

As shown in FIG. 4A, a substrate 220 may be provided with an insulating substrate 221, a first conductive pattern 222, a solder-resist layer 225, a second conductive pattern 226, and a substrate-insulating layer 227. The insulating substrate 221 may have opposed major surfaces that respectively support the first and the second conductive patterns 222, 226. For example, a first major surface of the insulating substrate 221 (e.g., the surface facing upward in FIG. 4A) may support the first conductive pattern 222. The first conductive pattern 222 may include a substrate pad 223 and a bump pad 224 connected electrically to the substrate pad 223. The solder-resist layer 225 may be provided on the first major surface of the insulating substrate 221. The substrate pad 223 and the ball pad 224 may be exposed through the solder-resist layer 225.

A second major surface of the insulating substrate 221 (e.g., the surface facing downward in FIG. 4A) may support the second conductive pattern 226. The second conductive pattern 226 may be electrically connected to the first conductive pattern 222 by a metal line (not shown) in a via hole (not shown) provided in the substrate 220. The substrate- insulating layer 227 may be provided on the second major surface of the insulating substrate 221. The substrate-insulating layer 227 may cover the second conductive pattern 226.

In this example embodiment, the substrate 220 has a structure of double-sided type having a first conductive pattern 222 and a second conductive pattern 226. In alternative embodiments, however, the substrate 220 may be of a single-sided type having only a first conductive pattern 222. If a single-sided substrate were implemented, then a semiconductor chip (e.g., see the semiconductor chip 210 in FIG. 41) may be mounted on the second side of the insulating substrate 221.

As shown in FIG. 4B, a first mask pattern 301 may be provided on the substrate-insulating layer 227. The first mask pattern 301 may be located at end portions of the substrate-insulating layer 227. The first mask pattern 301 may include an open area having a width M1. The width M1 may be greater than a width WC of a semiconductor chip (210 in FIG. 4I). In this way, the semiconductor chip (210 in FIG. 4I) may be mounted in the first concave part (227a in FIG. 4C), which may be formed by the first mask pattern 301 (explained in detail below). The first mask pattern 301 may be, for example, a photoresist layer formed by a general photolithography process. Numerous photoresist materials and photolithography process, which are well known in this art, may be suitably implemented.

As shown in FIG. 4C, a bump pad 224 may be provided on a first major surface A1 of the substrate 220, and the first concave part 227a may be formed on a second major surface A2 (which is opposite to the first major surface A1). The first concave part 227a may be formed in the substrate-insulating layer via an etching process, for example. By etching the substrate-insulating layer 227, the first concave part 227a may be formed in a stepped surface shape from the second surface A2. For example, the first concave part 227a may be recessed from the second surface A2. The first concave part 227a may be formed by (for example) dry etching, wet etching, and/or laser beam machining. An etching process by laser beam machining may provide accurate etching and process simplification. Among the laser beams, an excimer laser having a laser source such as Nd-YAG laser (for example) may be suitably implemented.

The first mask pattern 301 may fabricated from a chromium (Cr) membrane provided on quartz, for example. It will be appreciated, however, that the first mask pattern 301 may be fabricated from numerous other alternative materials. In this example embodiment, the first concave part 227a may have a rectangular parallelepiped shape. In alternative example embodiments, the first concave parts 227a may have any other geometric shape. If the substrate 220 is a single pattern type (instead of a double pattern type, as shown in FIG. 4C), then etching may be applied directly to the insulating substrate 221, or a designated protective layer (not shown) on the insulating substrate 221.

As shown in FIG. 4D, the first mask pattern 301 may be removed from the substrate-insulating layer 227.

As shown in FIG. 4E, the first concave part 227a may be filled with a filling compound 302. The filling compound 302 may be fabricated from a variety of materials that are well known in this art. A second mask pattern 303 may be formed on the substrate-insulating layer 227 and the filling compound 302. The second mask pattern 303 may include an open area having a width M2. The width M2 may be greater than a width WW of a substrate window W1 (shown in FIG. 4G), so that a second concave part 227b (shown in FIG. 4G) may remain after formation of the substrate window W1 (described in detail below). Also, the width M2 may be smaller than the width M1 of the open area of the first mask pattern 301 in FIG. 4B.

As shown in FIG. 4F, the second concave part 227b may be formed in a shape of stepped surface from the first concave part 227a. For example, the second concave part 227b may be recessed from a bottom surface of the first concave part 227a. The second concave part 227a may be provided by a second etching of the substrate-insulating layer 227. In this example embodiment, the second etching may be carried out until the portion of the substrate-insulating layer 227 exposed through the second mask patter 303 is completely removed from the insulating substrate 221. The filling compound 302 and the second mask pattern 303 in FIG. 4E may be removed. The second concave part 227b may have a rectangular parallelepiped shape. In alternative example embodiments, the second concave parts 227b may have any other geometric shape. It will be appreciated that the first and the second concave parts 227a, 227b, respectively, may be of similar shapes or different shapes.

As shown in FIG. 40, a substrate window W1 may be provided in the substrate 220. The substrate window W1 may be formed (for example) by punching the substrate 220. In this example embodiment, the substrate window W1 may be located at a center of the second concave part 227b. A bottom of the second concave part 227b may surround the substrate window W1. In alternative embodiments, the substrate window W1 may be provided at some other location through the substrate 220. The substrate window W1 may be formed by a stamping machine, and a protective tape may be used to protect both sides of the substrate 220.

As shown in FIGS. 4H and 4I, a chip-adhesion layer 304 may be provided in the first concave part 227a of the substrate-insulating layer 227. By way of example only, and not as a limitation of the invention, the chip-adhesion layer 304 may be applied via a printing process. Numerous and alternative application processes, which are well known in this art, may be suitably implemented. The printing thickness t1 of the chip adhesion-layer 304 may be greater than a depth L1 of the first concave part 227a. By way of example only, the printing thickness t1 of the chip-adhesion layer 304 may be within 1.3 to 2 times the depth L1 of the first concave part 227a.

As shown in FIG. 4I, the semiconductor chip 210 may be mounted in the first concave part 227a of the substrate 220. The semiconductor chip 210 may be located so that a chip pad 212 of the semiconductor chip 210 may be exposed through the substrate window W1. In the case that the semiconductor chip 210 is a center-pad type as shown in FIG. 4I (for example), the chip pad 212 of the semiconductor chip 210 may be exposed through a passivation layer 213. The semiconductor chip 210 and the substrate 220 may be pressed toward each other.

As the components are pressed together, the semiconductor chip 210 may move into the first concave part 227a and may displace the adhesive of the chip-adhesion layer 304. The height L3 between the bottom of the second concave part 227b (which may surround the substrate window W1) and the upper surface of the semiconductor chip 210 may become greater than the thickness t2 of the chip-adhesion layer 304. Here, the flow rate of the adhesive of the chip adhesion-layer 304 in the second concave part 227b may be smaller than that in the first concave part 227a. Accordingly, the fluidity of the adhesive in the directions P1 and P2 in the chip-adhesion layer 304 may be decreased.

The various adhesive flow rates through the first and the second concave parts 227a, 227b, respectively, may be explained via a Bernoulli's theorem. Consider a continuous fluid path having a narrow path portion and a wide path portion. According to a Bernoulli's theorem, a fluid velocity at the narrow path portion may be higher than that at the wide path portion. In the example embodiment, a path between the bottom of the second concave part 227b and the semiconductor chip 210 may correspond to the “wide path portion,” and a path between the bottom of the first concave part 227a and the semiconductor chip 210 may correspond to the “narrow path portion.” The fluid velocity at the “wide path portion,” (i.e. the path between the bottom of the second concave part 227b and the semiconductor chip 210) may be decreased, which may slow an approach of the flowing adhesive to the chip pad 212. The relatively slow adhesive flow in the second concave part 227b may protect the chip pad 212 from being contaminated by the adhesive.

On the other hand, the thickness t2 of the chip-adhesion layer 304 may be greater than a clearance L2 (a “narrow path portion”) between a sidewall of the first concave part 227a and the confronting sidewall 210a of the semiconductor chip 210. Accordingly, the fluid velocity at the clearance L2 corresponding to the “narrow path portion” may be greater than that at the thickness t2 corresponding to the “wide path portion.” Accordingly, adhesive in the chip-adhesion layer 304 may flow through the clearance L2 and forms a protrusion 304b of adhesive between the semiconductor chip 210 and the substrate 220. This protrusion 304b of adhesive may fix the semiconductor chip 210 to the substrate 220, and may inhibit the penetration of aqueous sealant into the boundary between the semiconductor chip 210 and the substrate 220.

As shown in FIG. 4J, the substrate pad 223 may be electrically connected to the chip pad 212 with a wire 240. By way of example only, the wire 240 may be fabricated from gold (Au). Of course the wire 240 may be fabricated from numerous other alternative materials that are well known in this art.

As shown in FIG. 4K, the substrate pad 223, the chip pad 212, the wire 240 and portions of the semiconductor chip 210 may be sealed with sealants 260 and 270.

As shown in FIG. 4L, a solder bump 250 may be provided on the bump pad 224. The solder bump 250 may serve as an external terminal of the WBGA semiconductor package 200. The adhesive strength of the solder bump 250 may be enhanced via providing an under bump metallization (UBM) layer (not shown) between the bump pad 224 and the solder bump 250. By way of example only, the UBM layer may be fabricated from materials such as nickel (Ni) and chromium (Cr).

The following is a detailed description of a structure of a WBGA semiconductor package in accordance with an example, non-limiting embodiment of the present invention.

As shown in FIG. 4L, a WBGA semiconductor package 200 may include a semiconductor chip 210, a substrate 220, a chip-adhesion layer 304, a wire 240, sealants 260 and 270, and a solder bump 250.

The substrate 220 may include an insulating substrate 221 made of an insulating material, a first conductive pattern 222, a solder-resist layer 225, a second conductive pattern 226, and a substrate-insulating layer 227. The first conductive pattern 222 may include a substrate pad 223 and a bump pad 224 electrically connected to the substrate pad 223. The first conductive pattern 222 may be provided on a first major surface of the insulating substrate 221. The solder-resist layer 225 may be provided on the first major surface of the insulating substrate 221. The substrate pad 223 and the bump pad 224 may be exposed through the solder-resist layer 225. The second conductive pattern 226 may be provided on a second major surface of the insulating substrate 221. The second conductive pattern 226 may be electrically connected to the first conductive pattern 222 through a metal line (not shown) in a via hole (not shown) provided in the substrate 220. The substrate-insulating layer 227 may be provided on the second major surface of the insulating substrate 221. The substrate-insulating layer 227 may cover the second conductive pattern 226. A substrate window W1 may be provided through the substrate 220. The substrate window W1 may pierce the substrate 220 perpendicularly.

A first concave part 227a may be provided in the substrate to accommodate the semiconductor chip 210. The first concave part 227a may be formed by etching the substrate-insulating layer 227.

A second concave part 227b may be provided in the first concave part 227a. The second concave part 227b may be provided around the circumference of the substrate window W1. The second concave part 227b may be formed by etching the bottom surface of the first concave part 227a.

A chip-adhesion layer 304 may be provided between the substrate 220 and the semiconductor chip 210. The thickness t2 of the chip-adhesion layer 304 may be greater than the clearance L2 between the sidewall of the first concave part 227a and the confronting sidewall of the semiconductor chip 210. A chip-adhesion layer 304a having a thickness L3 may be provided between the second concave part 227b and the semiconductor chip 210. A projection 304b of adhesive may be formed on edges of the chip-adhesion layer 304.

The semiconductor chip 210 may include a passivation layer 213 provided on the chip substrate 211 and a chip pad 212. The chip pad 212 may be exposed through the passivation layer 213 and the substrate window W1.

The wire 240 may electrically connect the substrate pad 223 of the substrate 220 to the chip pad 212. The wire 240 may be fabricated from gold (Au), for example.

The sealants 260 and 270 may be fabricated from epoxy resin and the sealants 260 and 270 may seal the chip pad 212, the substrate pad 223, the wire 240 and a portion of the semiconductor chip 210, as shown in FIG. 4L. The sealants 260 and 270 may protect the semiconductor chip 210 and the wire 240 from a mechanical shock and/or an electrical shock.

The solder bump 250 may be provided on the bump pad 224. The solder bump 250 may serve as an external terminal of the WBGA semiconductor package 200.

The example embodiments have been described with respect to a WBGA semiconductor package in which the substrate may include a substrate window through which a bonding wire may extend. It will be appreciated, however, that alternative substrates and mounting techniques may be suitably implemented. For example, a substrate without a substrate window may be employed and the semiconductor chip may be mounted and electrically connected to the substrate without the use of bonding wires.

Example, non-limiting embodiments of the present invention have been disclosed for illustrative purposes. Those skilled in the art will appreciate that various substitutions, modifications, and changes are possible, without departing from the scope and spirit of the invention as defined by the appended claims. The invention is not limited to details of the example embodiments set fourth herein and/or the accompanying drawings.

What is claimed is:

1. A method comprising:
providing a substrate having a first conductive pattern, the first conductive pattern including a substrate pad and a bump pad that are electrically connected together;
forming a concave part in the substrate;
providing a substrate window through the concave part; and
mounting a semiconductor chip having a chip pad on the substrate, so that the chip pad is exposed through the substrate window.

2. The method of claim 1, wherein the substrate includes an insulating substrate having a first major surface supporting the first conductive pattern; and
wherein forming a concave part includes,
forming a first concave part by etching a second major surface of the insulating substrate, and
forming a second concave part by etching a region of the first concave part.

3. The method of claim 2, wherein, the semiconductor chip is mounted in the first concave part of the insulating substrate.

4. The method of claim 3, further comprising:
providing a chip-adhesion layer between the semiconductor chip and the first concave part of the insulating substrate, the thickness of the chip-adhesion layer being greater than a clearance between a sidewall of the semiconductor chip a sidewall of the first concave part of the insulating substrate confronting the sidewall of the semiconductor chip.

5. The method of claim 1, wherein the substrate includes an insulating substrate having a first major surface supporting the first conductive pattern and a second major surface supporting a second conductive pattern that is electrically connected to the first conductive pattern, and a substrate-insulating layer covering the second conductive pattern; and
wherein forming a concave part includes
forming a first concave part by etching the substrate-insulating layer, and
forming a second concave part by etching a region of the first concave part.

6. The method of claim 5, wherein, the semiconductor chip is mounted in the first concave part of the substrate-insulating layer.

7. The method of claim 6, further comprising:
providing a chip-adhesion layer between the semiconductor chip and the first concave part of the substrate-insulating layer, the thickness of the chip-adhesion layer being greater than a clearance between a sidewall of the semiconductor chip and a sidewall of the first concave part of the substrate-insulating layer confronting the sidewall of the semiconductor chip.

8. The method of claim 1, wherein the semiconductor chip is mounted in the concave part of the substrate.

9. The method of claim 1, further comprising:
wire bonding the substrate pad to the chip pad.

10. The method of claim 1, further comprising:
providing a solder bump on the bump pad.

11. The method of claim 1, further comprising:
punching the substrate to provide the substrate window through the concave part.

12. The method of claim 1, further comprising:
etching the substrate to form the concave part.

13. The method of claim 1, further comprising:
providing a chip-adhesion layer between the semiconductor chip and the substrate.

14. The method of claim 12, further comprising:
printing the chip-adhesion layer on the concave part of the substrate.

15. A semiconductor package comprising:
a substrate having a first major surface supporting a substrate pad and a bump pad electrically connected to the substrate pad, the substrate having a second major surface with a concave part;
a substrate window extending through the substrate and opening at the concave part; and
a semiconductor chip mounted on the substrate, the semiconductor chip having a chip pad exposed through the substrate window.

16. The semiconductor package of claim 15, further comprising:
a chip-adhesion layer provided between the semiconductor chip and the concave part, the thickness of the chip-adhesion layer being greater than a clearance between a sidewall of the semiconductor chip and a sidewall of the concave part confronting the sidewall of the semiconductor chip.

17. The semiconductor package of claim 15, wherein the semiconductor chip is mounted in the concave part.

18. The semiconductor package of claim 15, wherein the concave part includes a first concave part extending around the circumference of the substrate window, and a second concave part provided in the first concave part.

19. The semiconductor package of claim 18, further comprising:
a first chip-adhesion layer provided between the semiconductor chip and the first concave part, the thickness of the first chip-adhesion layer being greater than a clearance between the sidewall of the semiconductor chip and a sidewall of the first concave part confronting the sidewall of the semiconductor chip.

20. The semiconductor package of claim 19, further comprising:
a second chip-adhesion layer, having a thickness greater than that of the first chip- adhesion layer, provided between the second concave part and the semiconductor chip.

21. The semiconductor package of claim 15, further comprising:
a wire extending through the substrate window and electrically connecting the substrate pad to the chip pad.

22. The semiconductor package of claim 15, further comprising:
a solder bump provided on the bump pad.

23. The semiconductor package of claim 15, wherein the semiconductor package is a WBGA semiconductor package.

24. A semiconductor package comprising:
a substrate having a major surface with a concave part; and
a semiconductor chip mounted in the concave part.

25. A semiconductor package manufactured in accordance with the method of claim 1.
